(19) United States
(12) Patent Application Publication
(10) Pub. No.: US 2013/0037100 A1
(43) Pub. Date: Feb. 14, 2013

(54) Thin Film Photovoltaic Solar Cells

(71) Applicants: Charlotte Platzer Björkman, Uppsala (SE); Tobias Törndahl, Uppsala (SE); Adam Hultqvist, Uppsala (SE)

(72) Inventors: Charlotte Platzer Björkman, Uppsala (SE); Tobias Törndahl, Uppsala (SE); Adam Hultqvist, Uppsala (SE)

(21) Appl. No.: 13/640,007

(22) PCT Filed: Apr. 8, 2011
(86) PCT No.: PCT/SE11/50426

§ 371 Date: Oct. 8, 2012

Related U.S. Application Data
(60) Provisional application No. 61/322,316, filed on Apr. 9, 2010.

(51) Int. Cl. H01L 31/0216

(52) U.S. Cl. 136/256

(57) ABSTRACT

A thin film photovoltaic solar cell (1) comprises a back contact (11), a multicompound absorber layer (12), and a window layer (16). The multicompound absorber layer (12) is of a ternary or quaternary absorber material and at least one layer of the window layer (16) is a Zn—Sn—O layer with usual impurities. The thin film photovoltaic solar cell (1) is typically provided on a glass substrate (10).

### TECHNICAL FIELD

The present invention relates in general to solar cells and in particular to materials for use in window layers of thin film photovoltaic solar cells based on multicompound absorber layers, in particular ternary or quaternary absorbers.

### BACKGROUND

The sun is the most prominent source of renewable energy since it provides an average power density of 1000 W/m². Harvesting this renewable power source is therefore a key to lowering the CO₂ emissions and to achieve a sustainable energy supply in the future.

There are two main approaches for converting the sunlight into usable energy. The technologies that convert light into heat are defined as solar thermal conversions and can either transfer the heat to water supplies or convert it into electricity by heating a medium that passes through a turbine generator. Photovoltaic technologies on the other hand convert light directly into electricity and do therefore not require any moving parts or intermediate energy conversion steps.

Solar cells are units that use the photovoltaic conversion and do normally consist of thin crystalline silicon wafers with a thickness of 100 to 300 micrometers. However, it is both energy consuming and costly to purify the silicon enough to be a good solar cell material. Competing solar cell technologies have therefore evolved that lowers the cost and energy consumption per produced solar cell Watt. A prominent technology that is currently gaining market shares from the wafer based technology uses a thin film, typically a few micrometers in thickness of light absorbing material on a relatively cheap substrate such as glass, stainless steel or polymers.

There are currently three major materials that are commercially used for the light absorbing thin film; Cadmium Telluride (CdTe), amorphous silicon (a-Si) and Cu(In,Ga)Se₂ (CIGS). Several companies are producing large volumes of a-Si solar cells and First Solar, one of the biggest solar cell companies of today, is using CdTe. CIGS has on the other hand shown the best conversion efficiencies both on a lab scale and for full sized modules and has therefore better potential in the long run to become the most cost effective solar cells. This potential has already resulted in the initiation of small scale production at approximately 15 companies and production process development at approximately another 20 companies.

Apart from the common field of application and the general layered structure, these technologies are very different. For instance, back contact formation as well as optimum fabrication processes for the absorber layer is very different between the CdTe and CIGS technologies. As a consequence, the requirements of the buffer and window layers are also very different.

CdTe-based solar cells have a so called superstrate configuration: glass/TCO/CdS/CdTe/back contact, where the glass is both the substrate and the front glass. The production involves chemical etching and high temperature processing or post-annealing steps, allowing substantial interdiffusion and recrystallisation of layers. TCO is an abbreviation for transparent conducting oxide.

CIGS-based solar cells have typically a substrate configuration as: ZnO:Al/ZnO/CdS/CIGS/Mo/glass, wherein in the production the deposition sequence starts with the back contact (Mo) and ends with the front contact (ZnO:Al), i.e. the opposite order as compared to CdTe. The three first layers in the configuration here above, i.e. the three topmost layers in the final product, are commonly referred to as a window layer. The layer closest to the CIGS layer, in this case the CdS layer is commonly referred to as the buffer layer. Strong interdiffusion at interfaces is minimized by keeping the temperature below about 150-200° C. for all steps after the CIGS deposition. Higher temperatures severely degrade device performance.

While the CdS buffer layer in CIGS-based solar cells has been chosen for production reasons, because it gives excellent solar cell performance and high process stability, there are several drawbacks with this choice. Firstly, Cd is classified as a toxic within the European Union, in Japan and in the United States of America, which has put restrictions on the usage of the material itself and on the treatment of the by-products from processing it. Secondly, since the CdS layer is deposited in a chemical bath it cannot be a part of an inline vacuum process. Finally, the optical band gap of CdS is not large enough to let the incoming blue and ultraviolet light sunlight pass without being absorbed, which lowers the number of photons that can reach and be converted into electricity by the active CIGS layer.

Extensive research has been performed to find a replacement material for CdS that is transparent for sunlight, can be deposited in vacuum and is nontoxic. There are currently three candidates for an alternative buffer layer that fulfil all of the listed criteria.

Indium sulphide (InₓS_{y}) has shown great solar cell performance and is currently used in production using a non-vacuum spray process by Honda. The material properties of InₓS_{y} are unfortunately very sensitive to the conditions during vacuum depositions and it is therefore hard to achieve industrial reproducibility and good solar cell performance.

Zn(S,O,OH) buffer layers are already commercialized by Showa-Shell, but are currently deposited with a non-vacuum chemical bath. The Zn(S,O,OH) buffer layer shows great results on a laboratory scale if it is deposited by chemical vapour deposition methods, but these depositions has yet to be shown to work on an industrial scale.

Finally, Zn₁₋ₓMgₓO buffer layers have shown great solar cell performance by chemical vapour deposition methods and by sputtering. Even if sputtering Zn₁₋ₓMgₓO gives lower performance compared to using chemical vapour deposition methods, it is easy to industrialize sputtering and it has already shown promising results when used in combination with other thin buffer layers. Because of this potential the entire Zn₁₋ₓMgₓO material system is already disclosed for use in thin film solar cells, see e.g. the published U.S. Pat. No. 6,259,016 B1.

### SUMMARY

An object of the present invention is to provide high efficiency photovoltaic solar cells based on multicompound absorber layers of a ternary or quaternary absorber material having at least equally good characteristics as currently available high efficiency photovoltaic solar cells, but which are more environmentally friendly. Another object of the present invention is to provide efficient photovoltaic solar cells that can easily be integrated in mass production in a vacuum environment.

The above objects are achieved by thin film photovoltaic solar cell according to the enclosed independent patent claim. Preferred embodiments are defined by the dependent claims. In general words, a thin film photovoltaic solar cell comprises a back contact, a multicompound absorber layer, and a window layer. The multicompound absorber layer is of a ternary or quaternary absorber material and at least one layer in the window layer is a Zn—Sn—O layer with usual impurities.

One advantage with the present invention is that the Zn—Sn—O material does not include any toxic or rare elements, does not absorb sunlight and has shown equal performance compared to the reference solar cells that used CdS as a buffer layer. An industrial advantage for Zn—Sn—O is the possibility to deposit in vacuum, which enables inline vacuum processing. Additionally, the required minimum thickness of the buffer layer for good solar cell performance is very thin for the Zn—Sn—O material system, decreasing both the buffer layer deposition process time and the material usage. Further advantages are discussed in connection with particular embodiments described in the detailed description section.

### BRIEF DESCRIPTION OF THE DRAWINGS

The invention, together with further objects and advantages thereof, may best be understood by making reference to the following description taken together with the accompanying drawings, in which:

FIG. 1 is a schematic illustration of a standard prior art CIGS solar cell device structure;

FIG. 2 is a schematic illustration of an embodiment of a thin film photovoltaic solar cell comprising a Zn—Sn—O buffer layer;

FIGS. 3A-B are diagrams showing the average open circuit voltage and fill factors for some test samples of Zn—Sn—O used as a buffer layer on CIGS;

FIG. 4 is a diagram showing the quantum efficiency of a solar cell with the structure shown in FIG. 2 compared to the structure shown in FIG. 1;

FIG. 5 is a schematic illustration of another embodiment of a thin film photovoltaic solar cell comprising Zn—Sn—O as a highly resistive layer;

FIG. 6 is a diagram showing the quantum efficiency of a solar cell with the structure shown in FIG. 5 compared to the structure shown in FIG. 1;

FIG. 7 is a schematic illustration of yet another embodiment of a thin film photovoltaic solar cell comprising a Zn—Sn—O buffer layer, functioning as both buffer and highly resistive layer;

FIG. 8 is an alternative schematic illustration of the embodiment of FIG. 7; and

FIG. 9 is a diagram showing the quantum efficiency of CZTS solar cells with the structure shown in FIG. 2 compared to the structure shown in FIG. 1.

### DETAILED DESCRIPTION

Throughout the drawings, the same reference numbers are used for similar or corresponding elements.

In order to understand the correct terminology, the detailed description begins with a brief description of prior art CIGS solar cells.

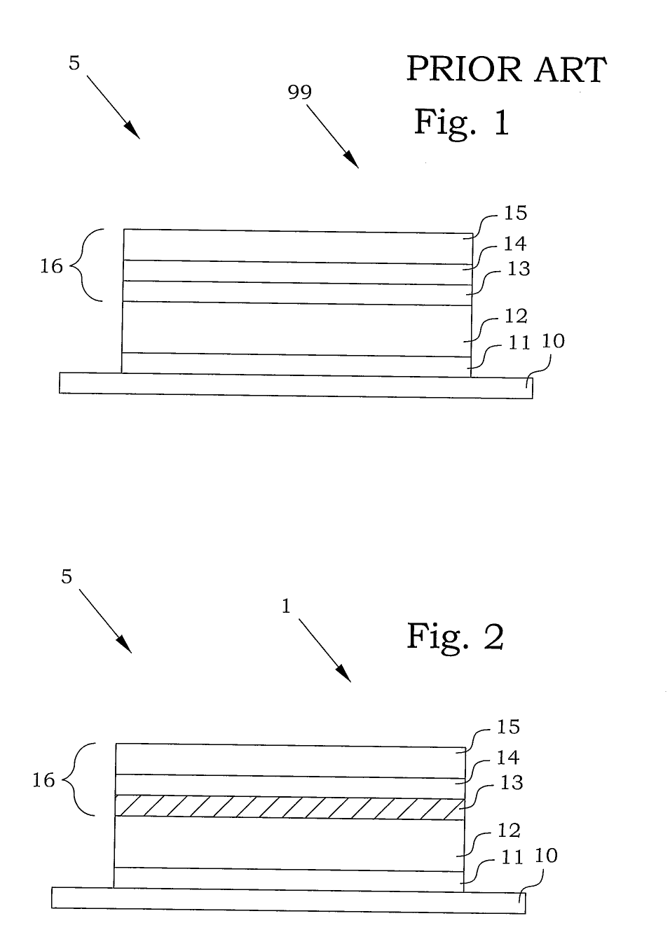

As depicted in FIG. 1, a typical CIGS solar cell 99 according to prior art generally consists of a stack 5 of five layers 11-15 deposited onto a substrate 10, typically of soda lime glass, metal or a flexible substrate. The first layer of the solar cell stack 5 is a, typically 200 to 300 nm thick, molybdenum (Mo) film that has been sputtered onto the glass substrate 10 and acts as an electrical back contact layer 11. A light absorbing multicompound absorber film 12, typically a CIGS film, is co-evaporated with a thickness of 1 to 3 μm on top of the Mo film. Following the CIGS film deposition, a 50 to 70 nm thick CdS layer is grown with chemical bath deposition. This CdS layer is generally denoted as a buffer layer 13 since it acts as an intermediate step in electrical and optical properties between the two neighbouring layers. A highly resistive layer 14, here a 70 to 90 nm thick ZnO layer is sputtered onto the buffer layer 13 to prevent electrical shunts between the top and the bottom contact of the device in case there are pinholes in the CIGS film. Finally a typically 200 to 400 nm thick and doped highly conductive ZnO layer is sputtered on the top and acts as an optically transparent electrical top contact, typically denoted as a transparent conductive oxide (TCO) layer 15. In this example, the buffer layer 13, the highly resistive layer 14 and the TCO layer 15 are together referred to as a window layer 16. The above description concerns only one example of a solar cell. Other devices with differing layer composition and/or thicknesses and/or deposition processes are also available in prior art.

The structure in FIG. 1 is the reference structure that is used today as the state of the art structure both in laboratories and industries, due to its high performance and long term stability.

A Zn—Sn—O layer is according to the present invention introduced in ternary or quaternary multicompound absorber layer thin film solar cells, such as CIGS solar cells, CZTS solar cells (see here below) or the like. A thin film photovoltaic solar cell according to the present invention comprises a back contact, a multicompound absorber layer and a window layer. The multicompound absorber layer is made of a ternary or quaternary absorber material. The window layer may in different embodiments comprise one or several layers. At least one layer in the window layer is a zinc-tin-oxide, Zn—Sn—O layer. The advantages, as described in the summary, are striking. As appreciated by the skilled person the Zn—Sn—O layer may comprise normal occurring contaminants or impurities such as hydrogen, carbon, nitrogen or other substances that are present during the different deposition processes. The term Zn—Sn—O layer should be understood to include all such variations.

In most embodiments presented in the present disclosure, CIGS has been used as a model absorber. However, the present invention is generally applicable for the use of a Zn—Sn—O layer for other ternary and quaternary multicompound absorber layers as well. New emerging absorbers such as, Cu₂(Zn,Sn)(S,Se)₄, CZTS, are developed for future use as possible cheap high efficiency thin film solar cell devices. A new world record of 9.6% conversion efficiency has been shown by IBM for a CZTS solar cell, where the solar cell stack, except the absorber layer, is identical to the configuration used for CIGS, shown in FIG. 1. Thus, it is reasonable to assume that the new Zn—Sn—O buffer layer will perform at a similar level as CdS in multicompound absorber layer based solar cells based on both CIGS and CZTS.

CZTS is attracting large attention as a potential replacement to CIGS. CZTS does not contain any elements with limited availability, allowing reduced materials cost. Today, there are concerns for the producers of CdTe and CIGS solar cells about the price and long term availability of indium and tellurium. CZTS crystallizes in a kesterite structure while the CIGS crystal structure is chalcopyrite. Both materials contain Cu and Se, in some cases also S. In CZTS indium and gallium is replaced by zinc and tin. In other words, multicompound absorber layers, in particular ternary or quaternary absorbers, preferably chalcopyrite, kesterite or stannite ternary or quaternary absorbers containing sulphur and/or selenium can be used.

As mentioned above, multicompound absorber layers that can be utilized in the present invention comprises in particular embodiments a group IB-IIIA-VIA₂ material, e.g. Cu(In,Ga)(S,Se)₂ and/or a group IB₂-IIB-IVA-VIA₄ material, e.g. Cu₂ZnSn(S,Se)₄. In the IB-IIIA-VIA₂ material, the group IB element could also be Ag and the group IIIA element Al. In the IB₂-IIB-IVA-VIA₄ material, the group IB element could also be Ag, the group IIB element Cd, the group IVA element Si or Ge.

The Zn—Sn—O layer is shown to be advantageous in several device configurations. In general, Zn—Sn—O can be used in any of the layers of the window layers. By “the window layer” is in the present disclosure understood, the layers provided above the bare absorber layer, i.e. from the first layer covering the absorber layer up to and including the TCO. The window layers may thereby e.g. comprise an absorber surface modification layer, a buffer layer, a highly resistive layer and/or a TCO layer. The Zn—Sn—O layer is preferably provided in such a close relationship with the absorber surface that it can influence the electronic properties of the junction.

For test evaluation of the electrical properties of CIGS devices with Zn—Sn—O buffer layers, sample devices are prepared using atomic layer deposition (ALD) as a deposition technique. The results of such tests are discussed further below. ALD is a suitable method for low temperature growth where the tin content in the Zn—Sn—O films can be precisely controlled. However, successful production of Zn—Sn—O buffer layers by other vacuum methods, such as sputtering or chemical vapour deposition (CVD), as well as non-vacuum methods is expected as well.

FIG. 2 shows a multicompound absorber layer solar cell, an embodiment of a thin film photovoltaic solar cell 1 according to the present invention, where a buffer layer 13 comprises Zn—Sn—O according to the invention instead of CdS according to prior art. This is indicated by the hatching of the buffer layer 13. In other words, the window layer 16 comprises a buffer layer 13 provided in direct contact with the multicompound absorber layer 12, and where the buffer layer 13 is a Zn—Sn—O layer.

An ALD process, in the present disclosure defined as Zn—Sn—O process 1, provides a buffer layer for a test system. Here, the Zn—Sn—O buffer layers are grown in a Microchemistry F-120 atomic layer deposition (ALD) reactor using nitrogen as carrier gas. Diethyl zinc [Zn(C₂H₅)₂ or DEZn] and tin(IV) t-butoxide [Sn(C₄H₉O)₄ or Sn(O^{t}Bu)₄] are used as metal sources, whereas deionised water is used as oxygen source. The desired [Sn]/([Sn]+[Zn]) content is obtained by controlling the DEZn to Sn(O^{t}Bu)₄ pulse ratio in the (DEZn/Sn(O^{t}Bu)₄:N₂:H₂O:N₂) ALD-cycle, where a process denoted Zn—Sn—O X:Y contains X DEZn/H₂O cycles for every Y Sn(O^{t}Bu)₄/H₂O cycles. Characteristic pulse lengths used in the process were 600/900:400:400:400 ms for the DEZn/Sn(O^{t}Bu)₄:N₂:H₂O:N₂ precursors, respectively.

Table 1 shows the average J(V) parameters for devices with Zn—Sn—O process 1 buffer layers according to one embodiment of the present invention, deposited on CIGS at 120° C. with the ALD technique. Corresponding parameters for a CdS buffer layer, a ZnO buffer layer and a SnOₓ buffer layer are also provided as references.

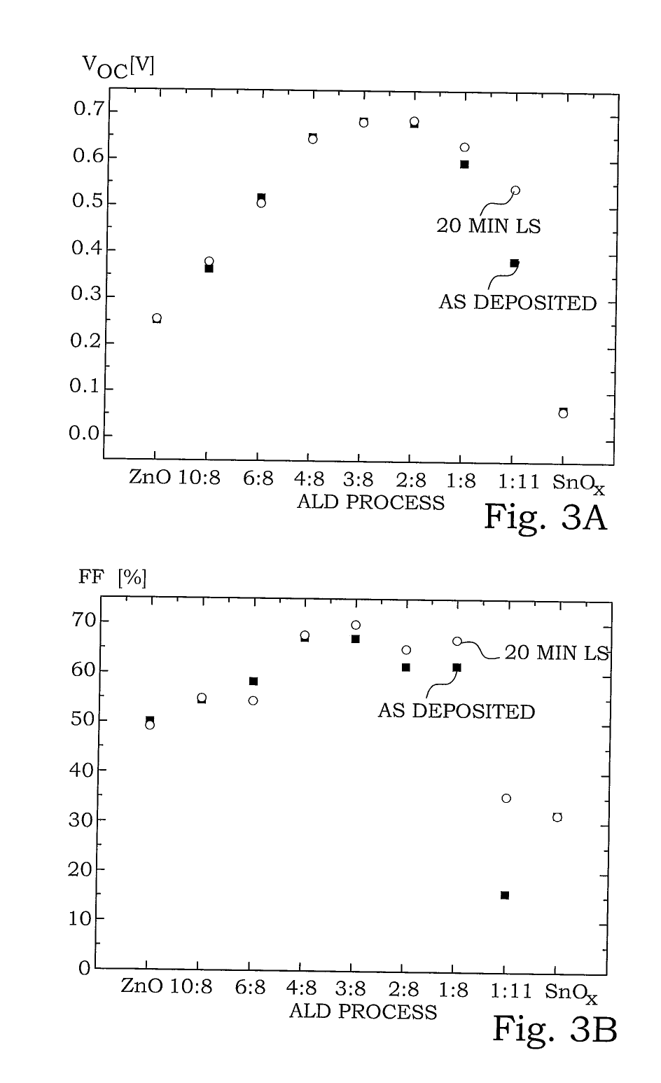

The solar cells based on Zn—Sn—O process 1 are analyzed as deposited and after light-soaking for 20 min. The diagram in FIG. 3A shows the open circuit voltage and the diagram in FIG. 3B displays the fill factor. As the ALD process is changed from ZnO to SnOₓ either by reducing the amount of Zn cycles or by increasing the amount of Sn cycles, a conversion efficiency optimum is obtained for a so called 3:8 process. The optimum is a result of coinciding maxima in both open circuit voltage (V_{oc}) and fill factor (FF). This process is thus defined as 3 DEZn/H₂O cycles for every 8 Sn(O^{t}Bu)₄/H₂O cycles. For growth on CuIn_{0.5}Ga_{0.5}Se₂, the [Sn]/([Sn]+[Zn]) content is estimated to be 0.1 for the 10:8 and 0.6 for the 1:11 processes, respectively. The values obtained for Zn—Sn—O used as a buffer layer on CIGS show that solar cells based on such structures very well can compete with conventional solar cells. The Zn—Sn—O material has in other words preferably a ratio [Sn]/([Sn]+[Zn]) between 0.1 and 0.6.

TABLE 1
Average parameters for devices with Zn—Sn—O buffer
layers on CIGS and CdS, ZnO or SnOₓ as buffer layer as
references.

| | V_{oc} | J_{sc}(QE) | FF | Efficiency |
|---|---|---|---|---|
| Buffer layer | [V] | [mA/cm²] | [%] | [%] |
| ZnO | 0.255 | 27.8 | 49.1 | 3.49 |
| 10:8 | 0.378 | 26.4 | 54.8 | 5.52 |
| 6:8 | 0.504 | 27.0 | 54.3 | 7.41 |
| 4:8 | 0.644 | 27.5 | 67.6 | 12.0 |
| 3:8 | 0.681 | 27.9 | 69.8 | 13.3 |
| 2:8 | 0.686 | 25.9 | 64.9 | 11.6 |
| 1:8 | 0.631 | 27.2 | 66.8 | 11.4 |
| 1:11 | 0.539 | 26.7 | 35.3 | 5.10 |
| SnOₓ | 0.0593 | 20.8 | 31.6 | 0.383 |
| CdS | 0.715 | 25.9 | 71.9 | 13.3 |

There are almost no variations in short circuit current, J_{sc}, as shown in Table 1, except for the significant drop for the SnOₓ cells. For the 3:8 ALD process the conversion efficiency of 13.3% (average value of 8 cells) is comparable to 13.3% (average value of 64 cells) for the CdS references. The general trend from Table 1 is that cells with Zn—Sn—O lose V_{oc} and FF, but gains J_{sc} compared to their CdS references. Previous studies show that high FF and V_{oc} for cells with CdS are the result of low recombination at the interface between buffer layer and absorber.

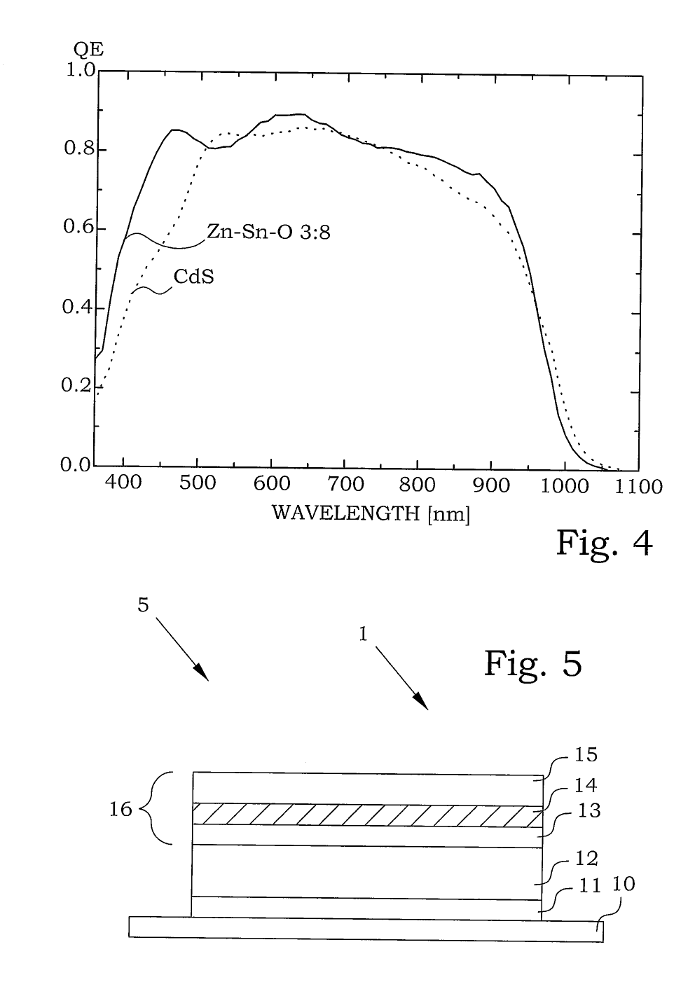

A corresponding quantum efficiency spectrum for Zn—Sn—O process 1, shown in FIG. 4, shows blue light in the 400-500 nm range being absorbed in the CdS but not in the ALD deposited Zn—Sn—O, which explains the gain in J_{sc} for the Zn—Sn—O buffer layers. FIG. 4 also illustrates the oscillatory behaviour in QE for the cells with Zn—Sn—O buffer layers, while the CdS references have smoother QE curves. The oscillations are probably due to a flatter more mirror like Zn—Sn—O surface that generates constructive interference for certain wavelengths, whereas the rougher CdS surface has less reflective properties.

In another test system, an ALD process, in the present disclosure defined as Zn—Sn—O process 2, provides a buffer layer for the solar cell defined in FIG. 2. Here, the Zn—Sn—O buffer layers are grown in a Microchemistry F-120 atomic layer deposition (ALD) reactor using nitrogen as carrier gas. The zinc precursor is DEZn, Zn(C₂H₅)₂, the tin precursor is TDMASn [tetrakis(dimethylamino) tin], Sn(N(CH₃)₂)₄ and the oxygen precursor is deionised water, H₂O. Both water and DEZn effuse into the chamber at room temperature, whereas the Sn precursor requires heating in a water bath to 40° C. to achieve a suitable vapour pressure by sublimation. The ALD process uses a Sn- or Zn-precursor:N₂:H₂O:N₂ pulse cycle with pulse lengths of 400 (for Sn and Zn):800:400:800 ms respectively. To control the [Sn]/([Sn]+[Zn]) content of the film the Sn/(Sn+Zn) pulse ratio in the ALD cycle is changed. As an example a Zn—Sn—O 3:2 buffer layer uses an average of three DEZ:N₂:H₂O:N₂ cycles for every two TDMASn:N₂:H₂O:N₂ cycles, hence has a Sn/(Sn+Zn) pulse ratio of 0.4.

The very best devices on CIGS for Zn—Sn—O process 2, are found within a Sn-content, defined as [Sn]/([Sn]+[Zn]), range of 0.15-0.21 as determined by Rutherford back scattering. The optimum is a result of coinciding maxima in both open circuit voltage (V_{oc}) and fill factor (FF). Good device performance was also obtained in the broader [Sn]/([Sn]+[Zn]) range of 0.1-0.25. The Ga content, [Ga]/([In]+[Ga]), of the CIGS in the described series was graded throughout the absorber layer with an average value of 0.43 as determined by XRF (X-ray fluorescence). However, it is not unlikely that the optimum [Sn]/([Sn]+[Zn]) ratio changes for CIGS with different band gap, i.e., different Ga content. Therefore, a reoptimization of the buffer layer process is needed for every new type of CIGS. At these Sn contents the Zn—Sn—O films are X-ray amorphous as determined by grazing incidence X-ray diffraction, GI-XRD, performed at an incidence angle of 0.3°. Finally, preliminary data suggests that the resistivity is greater than 1 Ωcm for these Zn—Sn—O films as measured by a four point probe setup for the sheet resistance and by X-ray reflectivity for the thickness of the films.

The best solar cell performance for Zn—Sn—O process 2 is achieved for thicknesses in the range of 20-150 nm. Good performance can be achieved in a wider range of 10-300 nm, where a 10 nm buffer layer suffers from a slightly lower FF and a 300 nm buffer layer shows reduced FF and V_{oc}. Good solar cell stability is shown for a 60 nm thick [determined from TEM (transmission electron microscope) investigations] Zn—Sn—O buffer layer, where the device performance did not degrade after 1000 h of dry heat testing at 85° C. In comparison, a 10 nm thick buffer layer suffers from severe degradation of the solar cell performance after 1000 h at room temperature without even being subjected to dry heat.

It is possible that the maxima in solar cell efficiency can be explained by the conduction band offset (CBO) theory, which proposes that a certain small positive CBO between the buffer layer and the absorber is optimal for the performance of CIGS solar cells. In this case, as the ALD process is varied it is possible that the CBO also varies and that it in some processes reaches a value that generates the best solar cell performance. For Zn—Sn—O with optimal composition, the structure is however amorphous which makes it hard to define the band gap and the position of the conduction band, which in turn makes it hard to apply the CBO theory. The absorption in the short wavelength region is reduced as compared to ZnO, but it is not clear if there is a shift in band gap or if the reduced absorption is due to for example an indirect band gap or other effects. The band gap of SnO has been reported to between 2.5 and 3.0 eV and for SnO₂ to 3.6-4.3 eV. An indirect band gap of SnO has been predicted theoretically. Whether amorphous Zn—Sn—O has a better matching electron affinity to CIGS than for example ZnO is very difficult to predict and also to determine experimentally due to the amorphous structure. Amorphous materials typically show substantial tailing at band edges and it is hard to define the band gap and band edges.

It is, however, clear from the experiments, that gains in V_{oc} and FF are present by using Zn—Sn—O as compared to using the pure oxide binary phases, ZnO and SnOₓ. It is presently believed that the ratio [Sn]/([Sn]+[Zn]) has to be at least 0.05 to noticeably increase the V_{oc} and FF from that of pure ZnO. At the high Sn content end, it is believed that [Sn]/([Sn]+[Zn]) values as high as 0.6 would present enhancements in V_{oc} and FF as compared to that of ZnO.

FIG. 2 shows the configuration proven experimentally by two different processes here above, where Zn—Sn—O replaces the standard CdS layer. Thus, according to one embodiment of the present invention, there is provided a multicompound absorber layer thin film solar cell, e.g. a CIGS solar cell comprising a Zn—Sn—O buffer layer. The solar cell is devoid of cadmium or CdS and comprises a Zn—Sn—O buffer layer. In this particular embodiment, the CIGS solar cell has five layers and the Zn—Sn—O constitutes the third layer from the top. Here, the benefits are to avoid Cd, increase the current by less absorbing Zn—Sn—O and to avoid non-vacuum deposition techniques.

FIG. 5 shows a multicompound absorber layer solar cell 1 according to one embodiment of the present invention. A thin buffer layer 13 of for example CdS, InₓS_{y} or (Zn,Mg,Sn)(S,Se,O,OH) (comprising one or several of the elements in each parenthesis) is followed by a Zn—Sn—O layer. In other words, the transparent, highly resistive layer 14 in the window layer 16 comprises Zn—Sn—O, possibly with usual impurities.

This improves efficiency similarly to what has been shown using Zn₁₋ₓMgₓO as a buffer layer 13 and also allows deposition of the Zn—Sn—O layer with a fast method such as sputtering. The thin buffer layer 13 then additionally functions as protection against sputter damage, but can be kept extremely thin, typically with a thickness below 50 nm, and preferably in the range of 5-30 nm.

An investigation of Zn—Sn—O films as exchange for the ZnO was done by replacing the standard CdS (60-70 nm) and ZnO (80-90 nm) stack by a thinner CdS layer (30-40 nm) and an ALD Zn—Sn—O (70-80 nm) layer stack. The resulting cells with a thin CdS/Zn—Sn—O stack, corresponding to the device structure shown in FIG. 5, have an efficiency of 14.0%=618 mV, J_{sc}=31.6 mA/cm² and FF=71.5%) compared to an efficiency of 13.4% (V_{oc}=620 mV, J_{sc}=29.4 mA/cm² and FF=73.5%) of the solar cells using the standard CdS/ZnO stack, corresponding to the device structure shown in FIG. 1.

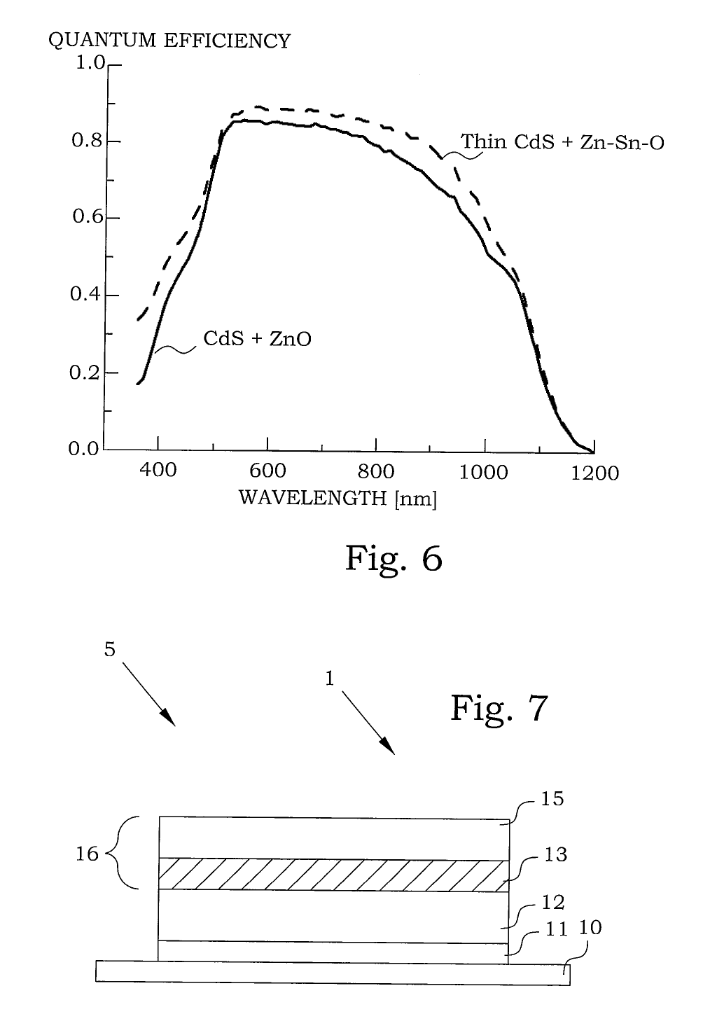

Thus, in the structure in FIG. 5 the highly resistive layer 14 of ZnO of FIG. 1 is replaced by Zn—Sn—O. This structure increases the quantum efficiency at all wavelengths as shown in FIG. 6 and as a result the total current density of the devices. One of the reasons for this is that it is possible to use a thinner CdS layer with this structure (even if the thickness of the Zn—Sn—O layer is in the same magnitude range as for the replaced ZnO layer) which reduces the blue light absorption of the buffer layer and as a bonus it also reduces the process time. The buffer layer and the highly resistive layer together have typically a thickness between 40 and 350 nm, and preferably between 50 and 200 nm.

In the structure in FIG. 7 the ZnO layer in FIG. 2 is completely removed, which in turn removes an entire deposition step during production. This is a great advantage in terms of cost, material and time for large scale production. Additionally, devices with structure like in FIG. 7 can have higher short circuit current densities and efficiencies compared to devices with structures like FIG. 2. Just as for FIG. 2, FIG. 7 device structures are completely Cd free and could be deposited in line while keeping it in vacuum.

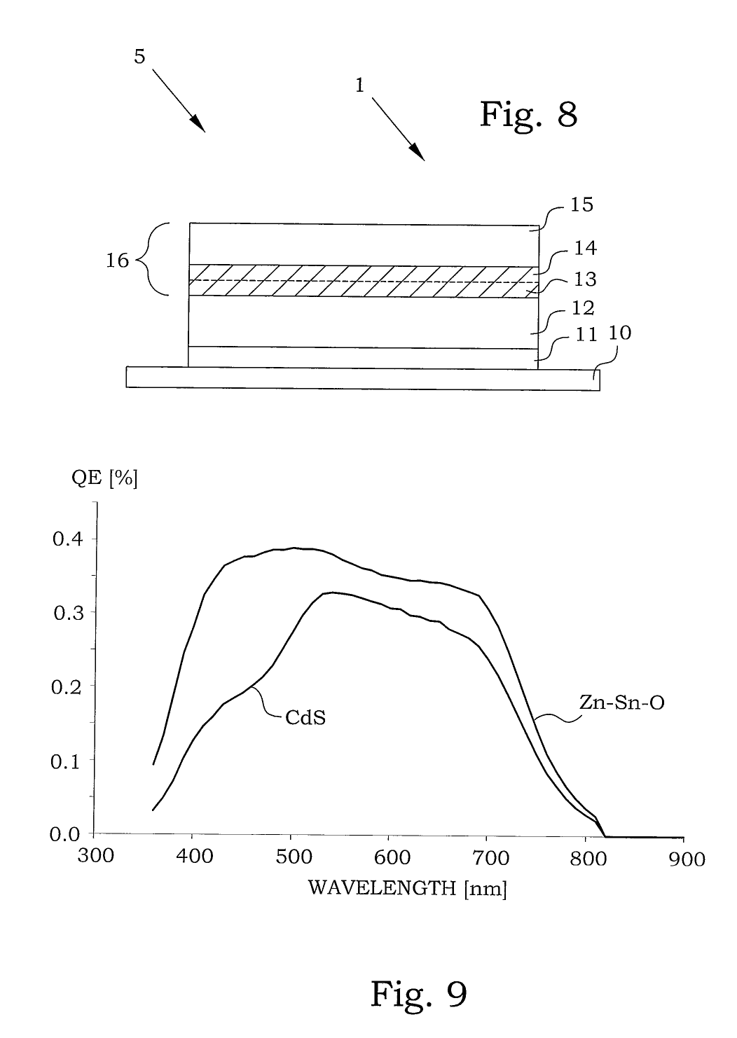

Since the undoped Zn—Sn—O material is highly resistive in itself, the embodiment in FIG. 7 can also be interpreted as if both a buffer layer 13 and a highly resistive layer 14 are present as a common Zn—Sn—O layer. Such an interpretation is schematically illustrated in FIG. 8. However, the two layers, i.e. buffer layer 13 and a highly resistive layer 14, are fully integrated and impossible to distinguish from each other.

Table 2 shows the average J(V) parameters (average value of 16 cells) for devices with Zn—Sn—O process 2 buffer layers (70 nm thick) deposited on CIGS at 120° C. with the ALD technique. According to the embodiment of FIG. 7 of the present invention, the highly resistive ZnO layer can be removed from the solar cell device structure without losing cell efficiency. Corresponding parameters for a CdS buffer layer with a ZnO highly resistive layer are also provided as reference.

TABLE 2
Comparison between a Zn—Sn—O buffer layer with and
without a highly resistive ZnO layer and a CdS reference
device on CIGS absorbers.

| | V_{oc} | J_{sc} | FF | Efficiency |
|---|---|---|---|---|
| Cell | (mV) | (mA/cm2) | (%) | (%) |
| CIGS/Zn—Sn—O | 660 | 34.3 | 72.8 | 16.5 |
| CIGS/Zn—Sn—O/ZnO | 662 | 33.2 | 71.8 | 15.8 |
| CIGS/CdS/ZnO | 675 | 31.1 | 74.7 | 15.6 |

The highly resistive ZnO layer in FIG. 2 can thus be omitted from the solar cell structure when using a Zn—Sn—O buffer layer as compared to a solar cell structure containing a CdS buffer layer (FIG. 1). For devices with Zn—Sn—O layers ranging from 20-300 nm in thickness on CIGS, the solar cell device performance is equal to or higher without the highly resistive ZnO layer than with the same layer included in the device structure. The gain in efficiency is mainly a result of higher J_{sc} for all different Zn—Sn—O thicknesses.

Also the TCO layer 15 can comprise Zn—Sn—O in a modified form. In the embodiment of FIG. 7 or 8, the TCO layer 15 can as one alternative be based on Zn—Sn—O with additional doping for achieving an increased conductivity. Thus, in such an embodiment, the standard so-called window layer (CdS/ZnO/ZnO:Al) is completely replaced by a Zn—Sn—O layer. Here, the top part of the Zn—Sn—O is made conductive by doping by for example In, Ga or Al. The doping is made in order to avoid resistive losses when Zn—Sn—O is used as a TCO. If the doping can be integrated in the deposition of the Zn—Sn—O layer, benefits include simplified processing, where the entire window layer may be provided as one single layer graded in composition.

The use of a doped Zn—Sn—O layer as TCO layer can be applied generally to other configurations as well, e.g. for thin film solar cells utilizing CdS and/or ZnO in other part layers of the window layer.

The Zn—Sn—O layer can appear at different positions within the window layer. However, the buffer layer and/or the highly resistive layer are the positions that provide the most prominent advantages.

ALD is as mentioned above one possible deposition method. The composition of the Zn—Sn—O films in all embodiments above may be controlled in between ZnO and SnOₓ by successively increasing the relative amount of tin to zinc in the growth process.

Sputtering is a high vacuum and high deposition rate method that is commercially available for large scale substrates today. Previous studies have shown that it is possible to sputter Zn—Sn—O films with excellent composition control and it is therefore an interesting method to deposit the Zn—Sn—O layers. While it has not been possible to sputter the buffer layer straight onto the absorber layer without losing performance, it would still be an interesting option for the Zn—Sn—O deposition in the structure in FIGS. 5 and 7.

Chemical vapour deposition, CVD, resembles ALD in that it uses a low vacuum process and gas flows of precursors to deposit the buffer layers. The main advantage of CVD as compared to ALD is that the precursors are all fed into the deposition zone at the same time and continuously, which removes the need of pulses. Thus, this can enable a much faster growth rate. Both ZnO and SnOₓ have previously been deposited by CVD from numerous precursors and it does therefore seem promising that a Zn—Sn—O process could be developed as well. A CVD process would be able to reduce the Zn—Sn—O deposition time compared to an ALD process in the device structure described earlier, potentially without losing solar cell performance and CVD is therefore a very interesting deposition method alternative.

The arguments for replacing CdS in CZTS-based solar cells with a less absorbing material without Cd are in principal the same as for CIGS: Increased current from reduced parasitic absorption, environmental gain from avoiding Cd and possibilities for dry, all-vacuum processing. In addition, the use of Zn—Sn—O buffer on Cu₂ZnSn(S,Se)₄ absorbers has a potential benefit in using the same elements (Zn and Sn) on both sides of the heterojunction. This can be beneficial for formation of a junction with low defect density.

Initial results using Zn—Sn—O instead of CdS in CZTS-based solar cells show that working devices can be made using CZTS/Zn—Sn—O junctions. The reproducibility in formation of the CZTS layer is still too poor to make a fair comparison between different cells, but as an example, a CZTS cell with CdS buffer layer is compared to a CZTS cell with Zn—Sn—O buffer layer in Table 3.

TABLE 3
Comparison between a Zn—Sn—O and CdS buffer layer
on CZTS absorbers.

| | V_{oc} | J_{sc} | FF | Efficiency |
|---|---|---|---|---|
| Cell | (mV) | (mA/cm²) | (%) | (%) |
| Cu₂ZnSnS₄/CdS | 440 | 6.1 | 39 | 1.1 |
| Cu₂ZnSnS₄/Zn—Sn—O | 327 | 7.8 | 27 | 0.7 |

FIG. 9 illustrates QE-curves of the two cells of Table 3. The diagram shows the expected gain in current from reduced absorption in the short wavelength region, 350-520 nm. The poor efficiency in the cases shown in the Table 3 is probably due to poor uniformity of the CZTS layer, with for example pin-holes causing shunting.

In the embodiments presented above, Mo has been assumed to be used as a back contact layer and a soda lime glass has been assumed to be used as a substrate. However, any type of substrate and back contact layer combination can be used. Non-excluding examples are other refractory metals as back contact layer, other types of glass substrates, polymer, metallic, ceramic non-glass substrates or embodiments where the substrate itself constitutes the back contact layer.

The embodiments described above are to be understood as a few illustrative examples of the present invention. It will be understood by those skilled in the art that various modifications, combinations and changes may be made to the embodiments without departing from the scope of the present invention. In particular, different part solutions in the different embodiments can be combined in other configurations, where technically possible. The scope of the present invention is, however, defined by the appended claims.

1.-21. (canceled)

22. A thin film photovoltaic solar cell, comprising:
a back contact;
a multicompound absorber layer of a ternary or quaternary absorber material; and
a window layer;
at least one layer of said window layer is a Zn—Sn—O layer with usual impurities.

23. The thin film photovoltaic solar cell according to claim 22, wherein said window layer comprises a buffer layer provided in direct contact with said multicompound absorber layer, whereby said Zn—Sn—O layer is said buffer layer.

24. The thin film photovoltaic solar cell according to claim 23, wherein said buffer layer has a thickness between 10 and 300 nm, preferably between 20 and 150 nm.

25. The thin film photovoltaic solar cell according to claim 22, wherein said window layer comprises a buffer layer provided in direct contact with said multicompound absorber layer and a highly resistive layer in direct contact with said buffer layer, whereby said Zn—Sn—O layer is said highly resistive layer.

26. The thin film photovoltaic solar cell according to claim 25, wherein said buffer layer has a thickness below 50 nm.

27. The thin film photovoltaic solar cell according to claim 25, wherein said buffer layer to a major part comprises CdS, InₓS_{y} or (Zn,Mg,Sn)(S,Se,O,OH) of one or several of the elements in each parenthesis.

28. The thin film photovoltaic solar cell according to claim 27, wherein said buffer layer and said highly resistive layer together have a thickness between 40 and 350 nm, preferably between 50 and 200 nm.

29. The thin film photovoltaic solar cell according to claim 27, wherein said Zn—Sn—O layer constitutes both said buffer layer and said highly resistive layer.

30. The thin film photovoltaic solar cell according to claim 29, said buffer layer and said highly resistive layer together have a thickness between 10 and 300 nm, preferably between 20 and 150 nm.

31. The thin film photovoltaic solar cell according to claim 22, wherein said window layer comprises a transparent conductive oxide layer, said transparent conductive oxide layer is a Zn—Sn—O layer doped with a conductance enhancing dopant.

32. The thin film photovoltaic solar cell according to claim 22, wherein said Zn—Sn—O layer has a ratio [Sn]/([Sn]+[Zn]) between 0.1 and 0.6.

33. The thin film photovoltaic solar cell according to claim 22, wherein said Zn—Sn—O layer is an amorphous material.

34. The thin film photovoltaic solar cell according to claim 22, wherein said multicompound absorber layer comprises a material selected from the group consisting of:
a IB-IIIA-VIA₂ material; and
a IB₂-IIB-IVA-VIA₄ material.

35. The thin film photovoltaic solar cell according to claim 34, wherein said IB element is at least one of Cu and Ag.

36. The thin film photovoltaic solar cell according to claim 34, wherein said multicompound absorber layer comprises a IB-IIIA-VIA₂ material.

37. The thin film photovoltaic solar cell according to claim 36, wherein said IIIA element is at least one of Ga, In and Al.

38. The thin film photovoltaic solar cell according to claim 37, wherein said multicompound absorber layer comprises Cu(In,Ga)(S,Se)₂.

39. The thin film photovoltaic solar cell according to claim 34, wherein said multicompound absorber layer comprises a IB₂-IIB-IVA-VIA₄ material.

40. The thin film photovoltaic solar cell according to claim 39, wherein said IIB element is at least one of Zn and Cd.

41. The thin film photovoltaic solar cell according to claim 39, wherein said IVA element is at least one of Sn, Si and Ge.

42. The thin film photovoltaic solar cell according to claim 41, wherein said multicompound absorber layer comprises Cu₂ZnSn(S,Se)₄.
